(19) United States
(12) Patent Application Publication
(10) Pub. No.: US 2010/0288550 A1
(43) Pub. Date: Nov. 18, 2010

(54) ELEMENT MOUNTING SUBSTRATE AND METHOD OF FABRICATING THE SAME, CIRCUIT DEVICE AND METHOD OF FABRICATING THE SAME, AND MOBILE APPLIANCE ( as amended

(76) Inventors: Masayuki Nagamatsu, Mizuho-city Gifu (JP); Ryosuke Usui, Aichi (JP); Yasunori Inoue, Gifu (JP)

Correspondence Address: MCDERMOTT WILL & EMERY LLP, 600 13TH STREET, N.W., WASHINGTON, DC, 20005-3096, US

(21) Appl. No.: 12/679,615

(22) PCT Filed: Jul. 28, 2008
(86) PCT No.: PCT/JP2008/063924

§ 371 Date: Jun. 18, 2010

(30) Foreign Application Priority Data
Sep. 28, 2007 (JP) 2007-256091

(51) Int. Cl. H05K 1/11

(52) U.S. Cl. 174/262

(57) ABSTRACT

There has been such a problem that conventional element mounting substrates and circuit devices using such substrates are not easily thinned, as there is a wiring layer formed on each of the substrates and that a part of the wiring layer is protruded and used as a bump electrode. In an element mounting substrate of this invention and a circuit device using such substrate, a through hole is arranged on an insulating base material, and a wiring layer is protruded from the surface of the insulating base material through the through hole. The protruding section of the wiring layer is used as a bump electrode, and a semiconductor element is mounted on the insulating base material. With such structure, the element mounting substrate is thinned, and the circuit device using such substrate is also thinned.

### TECHNICAL FIELD

The present invention relates to an element mounting substrate and a method of fabricating the same, a circuit device and a method of fabricating the same, and a mobile appliance. In particular, the present invention relates to an element mounting substrate using through-holes of the insulating base material to use, as bump electrodes, portions of a wiring layer that protrude from one main surface of an insulating base material, and a method of fabricating the same. Further, the present invention relates to a circuit device including such a substrate, a method of fabricating the same, and a mobile appliance.

### BACKGROUND ART

As an example of a conventional circuit substrate device and a method of fabricating the same, a circuit substrate device 161 and a method of fabricating the same have been known which will be described below using FIGS. 22 and 23. This technology is described for instance in Japanese Patent Application Publication No. 2002-76185.

FIG. 22 is a cross-sectional view of a circuit substrate device 161 disclosed in Japanese Patent Application Publication No. 2002-76185. FIGS. 23A to 23E are cross-sectional views for explaining a method of fabricating the circuit substrate device 161.

As shown in FIG. 22, wiring layers 163 are formed on an upper surface of an insulating substrate 162 made of resin. A protective layer 164 made of resin is formed on the upper surface of the insulating substrate 162 which includes the upper surfaces of the wiring layers 163. Protruding portions 165 and 166 that are portions of the wiring layer 163 protruding through opening portions of the protective layer 164 are used as conductive bumps.

A bare chip 167 is mounted on the insulating substrate 162. At this time, the bare chip 167 is mounted on the insulating substrate 162 so that tips of the protruding portions 165 and 166 as conductive bumps can be in contact with the pads 168 and 169 of the bare chip 167. The gap between the insulating substrate 162 and the bare chip 167 is filled with sealing resin 170.

On the other hand, via holes 171 and 172 are formed on a lower surface side of the insulating substrate 162, and a portion of the wiring layer 163 is exposed through the via holes 171 and 172. The circuit substrate device 161 is mounted on an external mounting substrate or the like through the portions of the wiring layer 163 exposed through the via holes 171 and 172.

As shown in FIG. 23A, a template 173 to be used as a face mold is prepared. In the template 173, recessed portions 174 and 175 are formed in areas where the protruding portions 165 and 166 (see FIG. 22) are disposed. Next, a seed layer 176 which is to be used as a cathode for electroplating to be performed later is formed on the template 173. Then, a resist film 177 is formed on the seed layer 176, and the resist film 177 is selectively removed to have openings in areas where the wiring layer 163 (see FIG. 23B) is to be formed.

As shown in FIG. 23B, the wiring layer 163 is formed by electroplating using the seed layer 176 as a cathode. At this time, the wiring layer 163 having a uniform film thickness is also formed inside the recessed portions 174 and 175. Next, the resist film 177 (see FIG. 23A) is removed.

As shown in FIG. 23C, the insulating substrate 162 is formed on the template 173, including on the wiring layer 163, using an electrodeposition method or the like, for example. The insulating substrate 162 is formed by using polyimide resin or the like which has high pliability and excellent flexibility. Next, the via holes 171 and 172 having diameters of approximately 100 μm are formed in the insulating substrate 162 with a carbon dioxide gas laser or the like.

As shown in FIG. 23D, the insulating substrate 162 is stripped from the template 173 (see FIG. 23C). At this time, the insulating substrate 162 is stripped at the interface between the template 173 and the seed layer 176 (see FIG. 23C). Accordingly, after that, the seed layer 176 (see FIG. 23A) is removed by wet etching. Next, the protective layer 164 made of epoxy resin or the like is formed on the upper surface of the insulating substrate 162 on which the wiring layer 163 is formed. At this time, the protective layer 164 is formed by applying epoxy resin in the form of varnish to the entire surface of the insulating substrate 162 by curtain coating or the like, and polymerizing and hardening the epoxy resin by curing. Then, resin formed on the tips of the protruding portions 165 and 166 as conductive bumps is wet etched using a potassium permanganate solution or the like. Thus, the tips of the protruding portions 165 and 166 are exposed from the protective layer 164.

As shown in FIG. 23E, a bare chip 167 is mounted on the protruding portions 165 and 166 as conductive bumps using a flip-chip bonder or the like. When the bare chip 167 is mounted, the entire circuit substrate device 161 is heated under a load. At this time, the sealing resin 170 disposed between the insulating substrate 162 and the bare chip 167 flows to fill the gap between the insulating substrate 162 and the bare chip 167.

### DISCLOSURE OF THE INVENTION

As described previously, in the conventional circuit substrate device 161, the wiring layer 163 is formed on the upper surface of the insulating substrate 162, and the protruding portions 165 and 166 of the wiring layer 163 are used as conductive bumps.

Further, the protruding portions 165 and 166 as conductive bumps and the respective pads 168 and 169 of the bare chip 167 are electrically connected to each other. This structure has the problem that it is difficult to reduce the thickness of the circuit substrate device 161 because the thickness of the circuit substrate device 161 includes the thickness of the insulating substrate 162 that is necessary for a portion located under the wiring layer 163. Since mobile appliances such as mobile phones, particularly, themselves have been becoming thinner and thinner, it has been desired to reduce the thickness and size of the circuit substrate device 161 to be mounted in such a mobile appliance.

Further, in the method of fabricating the circuit substrate device 161, the template 173 is used to form the protruding portions 165 and 166 in the wiring layer 163 on the upper surface of the insulating substrate 162. Thus, the method needs: the step of forming the seed layer 176, the wiring layer 163, and the insulating substrate 162 using the template 173 and stripping the insulating substrate 162 and the like from the template 173; the step of removing the seed layer 176 from the insulating substrate 162; and the like. Accordingly, there is a problem that the number of steps in a fabrication process is so large that it is difficult to reduce fabrication cost and fabrication time.

Moreover, in the method of fabricating the circuit substrate device 161, the recessed portions 174 and 175 formed in the template 173 determine the protruding heights of the protruding portions 165 and 166 of the wiring layer 163. This fabrication method therefore has a problem that the protruding heights of the protruding portions 165 and 166 cannot be easily changed in accordance with usage of when packaged.

The present invention has been made in view of the aforementioned circumstances, and provides an element mounting substrate including: an insulating base material having a pair of main surfaces; a through-hole penetrating the insulating base material to a side of one of the main surfaces from a side of the different main surface; and a wiring layer protruding in the through-hole from the different main surface side of the insulating base material to the one main surface side thereof. In the element mounting substrate, a protruding portion of the wiring layer is used as an electrode.

Further, a method of fabricating an element mounting substrate of the present invention includes the steps of: preparing an insulating base material, attaching a supporting member to the insulating base material on a side of one main surface, and attaching a conductive member to the insulating base material on a side of a different main surface opposite to the one main surface; selectively removing the conductive member, and forming a through-hole in the insulating base material using the conductive member as a mask; forming a wiring layer by forming a metal layer so that the metal layer covers the different main surface of the insulating base material and an inside of the through-hole and by selectively removing the metal layer, and stripping the supporting member; etching the insulating base material from the one main surface side of the insulating base material to cause a portion of the wiring layer to protrude from the one main surface of the insulating base material.

Further, a method of fabricating an element mounting substrate of the present invention includes the steps of: preparing an insulating base material, and attaching conductive members to the insulating base material on a side of one main surface and a side of a different main surface opposite to the one main surface; selectively removing the conductive member at the one main surface side of the insulating base material, and forming a through-hole in the insulating base material using the conductive member at the one main surface side as a mask; forming a wiring layer by forming a metal layer so that the metal layer fills the through-hole and covers the one main surface side of the insulating base material and by selectively removing the metal layer and the conductive member at the different main surface side of the insulating base material; and etching the insulating base material from the one main surface side of the insulating base material to cause a portion of the wiring layer to protrude from the one main surface of the insulating base material.

Further, a circuit device of the present invention includes an element mounting substrate and a circuit element mounted on the element mounting substrate, the element mounting substrate including an insulating base material having a pair of main surfaces, a through-hole penetrating the insulating base material, and a wiring layer protruding in the through-hole from the different main surface side of the insulating base material to the one main surface side thereof. In the circuit device, a protruding portion of the wiring layer is used as an electrode electrically connecting to a pad electrode of the circuit element.

Further, a mobile appliance of the present invention includes a circuit device including an element mounting substrate and a circuit element mounted on the element mounting substrate, the element mounting substrate including an insulating base material having a pair of main surfaces, a through-hole penetrating the insulating base material, and a wiring layer protruding in the through-hole from the different main surface side of the insulating base material to the one main surface side thereof. In the mobile appliance, a protruding portion of the wiring layer is used as an electrode electrically connecting to a pad electrode of the circuit element.

In the present invention, a through-hole is formed in an insulating base material constituting an element mounting substrate, and a portion of a wiring layer protrudes from a front surface of the insulating base material through the through-hole. This structure realizes a reduction in the thickness of the element mounting substrate, and further realizes a reduction in the thickness of a circuit device using the element mounting substrate.

Further, in the present invention, the protruding portion of the wiring layer is used as a bump electrode of the element mounting substrate. This structure can increase the distance between the insulating base material and the semiconductor element having different thermal expansion coefficients, and reduce damage to a conductive material due to thermal stress caused by the difference in thermal expansion coefficient therebetween. Thus, connection reliability is improved.

Moreover, in the present invention, by using a portion of the wiring layer as a bump electrode, a thinned element mounting substrate can be used in a CSP-type circuit device, a WLP-type circuit device, or a multichip module.

Furthermore, in the present invention, by using a portion of the wiring layer as a bump electrode, a thinned element mounting substrate can also be used as a multilayer wiring substrate.

Also, in the present invention, by etching the insulating base material, a portion of the wiring layer which is formed in the through-hole of the insulating base material is caused to protrude from the front surface of the insulating base material. With this fabrication method, the protruding height of the protruding portion of the wiring layer which is used as a bump electrode can be easily adjusted. Thus, a fabrication process can be simplified.

Further, in the present invention, a conductive member to be used as a mask for use in forming the through-hole in the insulating base material is not removed, and the wiring layer is formed on the upper surface of the conductive member. This fabrication method can reduce the number of steps of a fabrication process and can simplify the fabrication process.

### BRIEF DESCRIPTION OF THE DRAWINGS

FIGS. 1A and 1B are cross-sectional views for explaining a circuit device using an element mounting substrate of a first embodiment of the present invention;

FIGS. 2 to 8 are cross-sectional views for explaining a method of fabricating the circuit device using the element mounting substrate of the first embodiment of the present invention;

FIG. 9 is a cross-sectional view showing a modified example of the first embodiment of the present invention;

FIGS. 10A and 10B are cross-sectional views for explaining a circuit device using an element mounting substrate of a second embodiment of the present invention;

FIGS. 11 to 17 are cross-sectional views for explaining a method of fabricating the circuit device using the element mounting substrate of the second embodiment of the present invention;

FIG. 18 is a cross-sectional view showing a modified example of the second embodiment of the present invention;

FIG. 19 is a cross-sectional view for explaining a circuit device using an element mounting substrate of a third embodiment of the present invention;

FIG. 20 is a cross-sectional view for explaining a circuit device using an element mounting substrate of a fourth embodiment of the present invention;

FIGS. 21A and 21B are a perspective view and a cross-sectional view for explaining a mobile appliance using an element mounting substrate of a fifth embodiment of the present invention, respectively;

FIG. 22 is a cross-sectional view for explaining a circuit substrate device of a conventional embodiment; and

FIGS. 23A to 23E are cross-sectional views for explaining a method of fabricating the circuit substrate device of the conventional embodiment.

### DESCRIPTION OF THE INVENTIONS

### First Embodiment

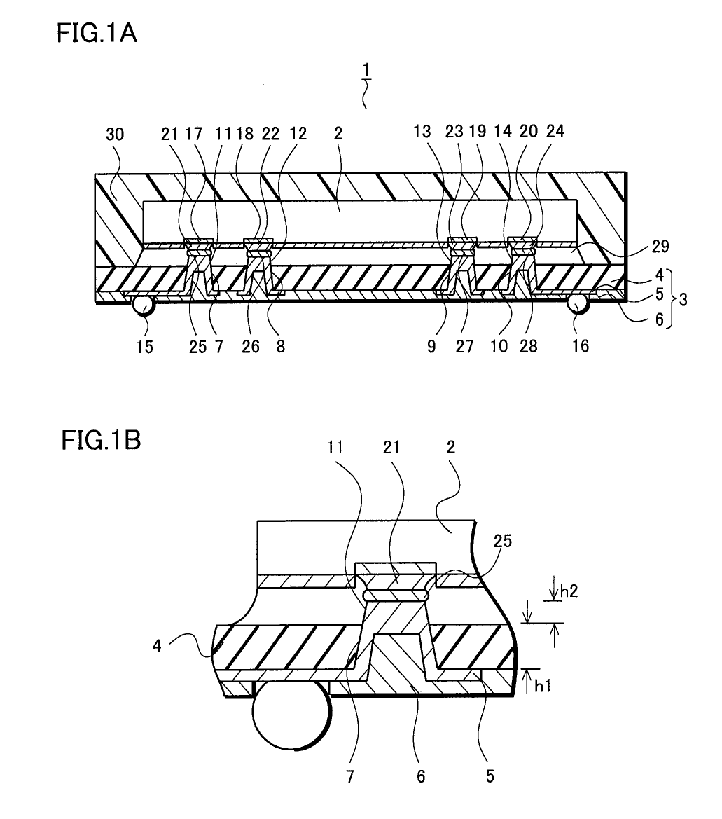

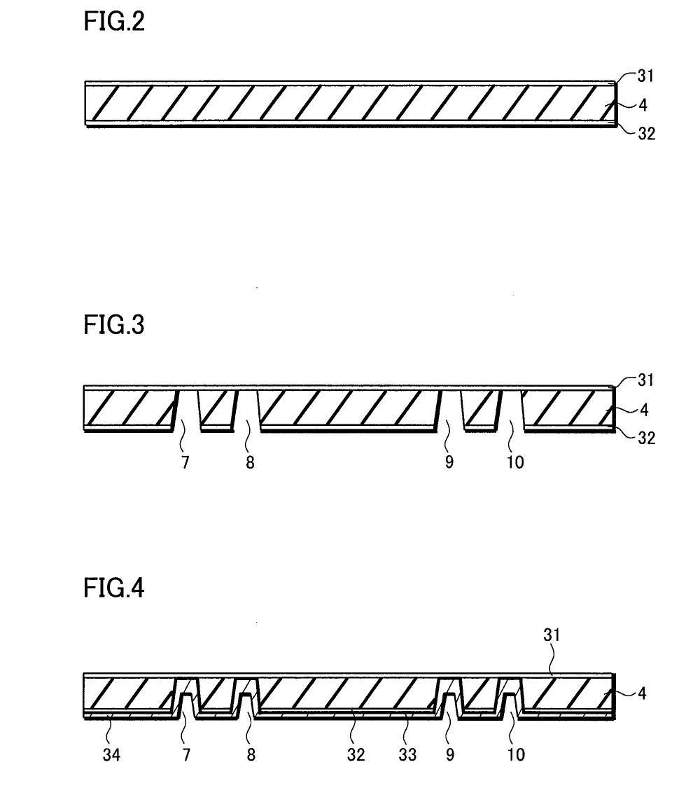

Hereinafter, a circuit device using an element mounting substrate of this embodiment and a method of fabricating the circuit device using the element mounting substrate will be described with reference to FIGS. 1A to 8. FIG. 1A is a cross-sectional view for explaining the circuit device using the element mounting substrate of this embodiment. FIG. 1B is a cross-sectional view for explaining a bump electrode of this embodiment. FIGS. 2 to 8 are cross-sectional views for explaining the method of fabricating the circuit device using the element mounting substrate of this embodiment. It should be noted that in an explanation of the circuit device and the method of fabricating the same in FIGS. 1A to 8, the element mounting substrate and a method of fabricating the same will be described together.

First, the circuit device using the element mounting substrate will be described with reference to FIGS. 1A and 1B.

As shown in FIGS. 1A and 1B, a circuit device 1 is a resin-sealed CSP (Chip Size Package) having slightly larger outside dimensions than that of a semiconductor element 2 embedded therein. The appearance of the circuit device 1 is in the shape of a rectangular parallelepiped or a cube. It should be noted that though in this embodiment a description will be made of the case of a CSP-type circuit device, the present application is not limited to this. For example, in the case of a WLP (Wafer Level Package) in which outside dimensions of a circuit device have substantially the same dimensions as those of a semiconductor element mounted thereon, similar effects can also be obtained.

An element mounting substrate 3 principally includes an insulating base material 4, a wiring layer 5 formed on the insulating base material 4, and a covering layer 6 for covering a back surface side of the insulating base material 4. It should be noted that the covering layer 6 may or may not be disposed on the back surface side of the insulating base material 4.

The insulating base material 4 is glass epoxy or the like obtained by impregnating fiberglass with epoxy resin, and is an interposer based on a resin material. The film thickness of the insulating base material 4 is, for example, 30 to 80 μm. The insulating base material 4 has the semiconductor element 2 mounted on the front surface side thereof, and has the wiring layer 5 formed on the back surface side thereof. The insulating base material 4 also has the function of mechanically supporting the semiconductor element 2 in a fabrication process. The insulating base material 4 may be made of a material other than a resin-based material, and, for example, may be a substrate made of ceramic or an inorganic material such as Si, or a substrate in which a substrate such as a metal substrate made of metal such as copper or aluminum is covered and insulated by an insulating layer made of resin or the like.

The wiring layer 5 is formed by selectively etching a Cu plated layer formed by, for example, electrolytic plating or the like. The film thickness of the wiring layer 5 is, for example, approximately 20 to 50 μm. The wiring layer 5 is disposed in a pattern on the back surface side of the insulating base material 4. The wiring layer 5 protrudes from the front surface of the insulating base material 4 through through-holes 7, 8, 9, and 10 formed in the insulating base material 4. Protruding portions 11, 12, 13, and 14 of the wiring layer 5 protrude above the through-holes 7, 8, 9, and 10 to be used as bump electrodes. It should be noted that though the protruding portions 11, 12, 13, and 14 protrude approximately 10 to 30 μm from a front surface of the insulating base material 4, any design change can be made to the protruding heights thereof in accordance with use. On the front surface side of the insulating base material 4, the wiring layer 5 is not disposed in a pattern, but only the protruding portions 11, 12, 13, and 14 are formed.

The covering layer 6 covers the back surface side of the insulating base material 4. In the covering layer 6, opening portions are formed in areas where external electrodes 15 and 16 are formed. The covering layer 6 is made of thermosetting resin such as epoxy resin or thermoplastic resin such as polyethylene. The thicknesses of portions of the covering layer 6 which cover the upper surface of the wiring layer 5 are, for example, approximately 20 to 100 μm. It should be noted that the covering layer 6 may also be a solder resist (PSR: Photo Solder Resist).

The external electrodes 15 and 16 are made of a conductive material such as solder and provided in the form of a grid on the back surface side of the insulating base material 4 to constitute a BGA (Ball Grid Array). The external electrodes 15 and 16 are electrically connected to the semiconductor element 2 embedded in the circuit device 1 through the wiring layer 5. It should be noted that since an SIP (System in Package) or the like may also be employed as a circuit device, the external electrodes 15 and 16 may be disposed in the form of a ring in the periphery of the insulating base material 4 or may be randomly disposed.

The semiconductor element 2 (circuit element) is connected to the top of the insulating base material 4 through the protruding portions 11, 12, 13, and 14. Specifically, on pad electrodes 17, 18, 19, and 20 of the semiconductor element 2, bump electrodes 21, 22, 23, and 24 made of, for example, Au are formed. The bump electrodes 21, 22, 23, and 24 of the semiconductor element 2 are respectively mounted on the protruding portions 11, 12, 13, and 14 with conductive materials 25, 26, 27, and 28 interposed therebetween by, for example, a flip-chip bonding technique. The conductive materials 25, 26, 27, and 28 are made of solder cream, brazing material, conductive paste, or the like.

It should be noted that though in this embodiment a description has been made of the case where the bump electrodes 21, 22, 23, and 24 are formed on the semiconductor element 2 side, the present invention is not limited to this case. For example, the present invention may be applied to the case where the pad electrodes 17, 18, 19, and 20 are electrically connected directly to the protruding portions 11, 12, 13, and 14 through the conductive materials 25, 26, 27, and 28, respectively. Further, the present invention may be applied to the case of resin bonding in which liquid resin or a resin sheet is disposed on the insulating base material 4 having the protruding portions 11, 12, 13, and 14 disposed therein and in which the semiconductor element 2 and the insulating base material 4 are connected to each other by applying pressure when mounting the semiconductor element 2 thereon and by curing the resin.

The semiconductor element 2 is employed here as a circuit element embedded in the circuit device 1. However, other circuit element may be employed. Specifically, an active element such as an IC, an LSI, a discrete transistor, or a discrete diode may be employed as a circuit element. Further, a passive element such as a chip resistor, a chip capacitor, or a sensor may be employed as a circuit element. Moreover, a system configured by internally connecting multiple passive and active elements in combination may be built in the circuit device 1. In this case, protruding portions of the wiring layer 5 are further disposed on the front surface side of the insulating base material 4, and passive elements such as a chip resistor are disposed adjacent to the semiconductor element 2 shown in FIG. 1A.

It should be noted that this element mounting substrate 3 can be applied to a module having only a circuit element mounted thereon, and a circuit device having a totally sealed substrate. Further, possible circuit elements to be mounted on such a substrate or such a circuit device are a semiconductor chip and a passive element. Also, these circuit elements are provided three-dimensionally in such a manner that multiple semiconductor chips are stacked, or provided two-dimensionally. In this way, multiple circuit elements are provided to constitute a system.

An underfill 29 is disposed to fill the gap between the semiconductor element 2 and the insulating base material 4 and made of, for example, epoxy resin. The underfill 29 is also used as a reinforcing material for bump connecting portions against thermal stress caused by the difference in thermal expansion coefficients between the semiconductor element 2 and the insulating base material 4. It should be noted that the thermal expansion coefficient and viscosity of the underfill 29 are adjusted by changing the content of filler mixed in the epoxy resin.

Sealing resin 30 is formed to cover the upper surfaces of the semiconductor element 2 and the insulating base material 4, and is made of thermosetting resin formed by transfer molding or thermoplastic resin formed by injection molding.

As shown in FIG. 1B, the insulating base material 4 has the through-hole 7 formed therein which penetrates from the back surface side thereof to the front surface side thereof. The wiring layer 5 is disposed in a pattern on the back surface side of the insulating base material 4, and protrudes from the front surface of the insulating base material 4 through the inner side surfaces of the through-holes 7. Although details will be described later when a circuit device fabrication method is described, the protruding portion 11 is formed by etching the insulating base material 4 from the front surface side of the insulating base material 4. Since the wiring layer 5 has a structure in which the wiring layer 5 is buried in the insulating base material 4, the thickness of the element mounting substrate 3 can be reduced by a thickness h1 of each portion of the wiring layer 5 which is used as a bump electrode. Further, the thickness of the circuit device 1 can be reduced.

On the other hand, a protruding height h2 by which the wiring layer 5 protrudes from the front surface of the insulating base material 4 is arbitrarily set in accordance with use when the wiring layer 5 is used as bump electrodes, by adjusting the amount of etching of the insulating base material 4. The distance between the insulating base material 4 and the semiconductor element 2 can be increased by increasing the protruding height h2. Thus, it is possible to reduce damage to the conductive material 25 due to thermal stress caused by the difference in thermal expansion coefficients between the insulating base material 4 and the semiconductor element 2, and to improve connection reliability. Further, by increasing the protruding height h2, the bump electrode 21 on the semiconductor element 2 side can be omitted, or the height of the bump electrode 21 can be reduced.

Next, a method of fabricating the circuit device using the element mounting substrate shown in FIG. 1A will be described with reference to FIGS. 2 to 8. It should be noted that the same components as those of the circuit device using the element mounting substrate shown in FIG. 1A are denoted by the same reference numerals.

As shown in FIG. 2, an insulating base material 4 is prepared, and Cu foil 31 and 32 as conductive members is attached to the entire front and back surfaces of the insulating base material 4 by, for example, plating, vapor deposition, sputtering, or rolling. The conductive members may be Al, Fe, or Fe—Ni foil other than Cu. As described previously, the insulating base material 4 is made of a resin material, an inorganic material, or a metal material (including a metal material having an insulated surface). The insulating base material 4 also has the function of mechanically supporting the semiconductor element 2 (see FIG. 1A) in a fabrication process.

It should be noted that the Cu foil 31 on the front surface side of the insulating base material 4 is stripped in a later step for forming a wiring layer, and therefore only needs to serve as a supporting member for supporting the insulating base material 4. Accordingly, the Cu foil 31 does not necessarily need to be a conductive member.

As shown in FIG. 3, through-holes 7, 8, 9, and 10 are formed from the back surface side of the insulating base material 4. Using a publicly known photolithographic technique, opening portions are formed in the Cu foil 32 on areas where the through-holes 7, 8, 9, and 10 are to be formed, by wet etching using an etchant, e.g., ferric chloride or copper chloride. Then, using the remaining Cu foil 32 as a mask, the insulating base material 4 is removed with a carbon dioxide laser until the Cu foil 31 is exposed. Thus, the through-holes 7, 8, 9, and 10 are formed. It should be noted that after the insulating base material 4 is evaporated with the carbon dioxide laser, if residues exist in bottom portions of the through-holes 7, 8, 9, and 10, the residues are removed by wet etching using an etchant such as sodium permanganate or ammonium persulfate.

As shown in FIG. 4, an electroless plated layer 33 having a thickness of, for example, approximately 1 μm is deposited by electroless plating on the insulating base material 4 at inner side surfaces of the through-holes 7, 8, 9, and 10, on the Cu foil 31 at bottom portions of the through-holes 7, 8, 9, and 10, and on the Cu foil 32 on the back surface side of the insulating base material 4. The electroless plated layer 33 may be made of the same material as the Cu foil 31 and 32 (e.g., Cu) or other metal material. It should be noted that in this step, the adhesion of the electroless plated layer 33 by the above-described electroless plating is performed with the upper surface of the Cu foil 31 entirely covered with a protective film (not shown).

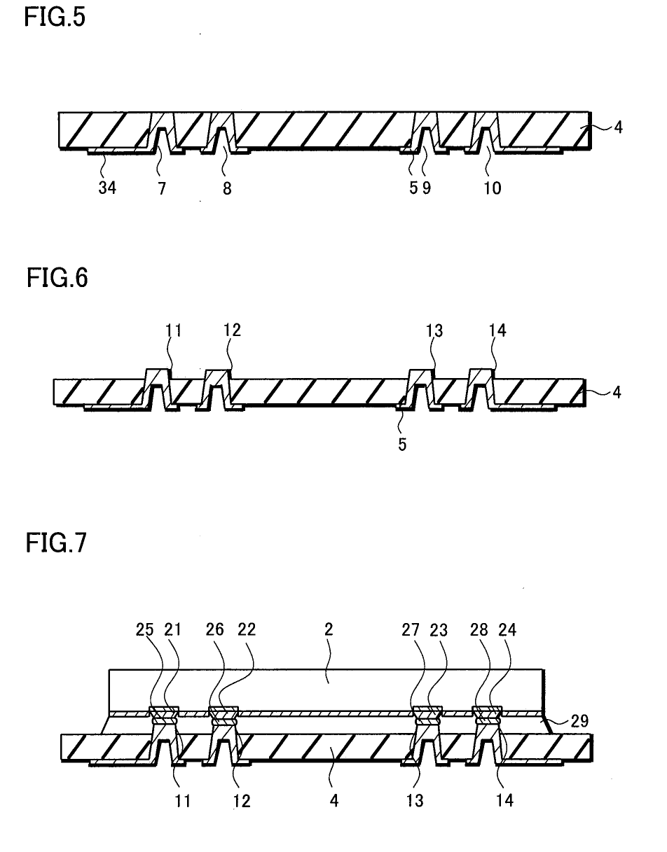

Next, using the electroless plated layer 33 like a plated wire for power supply, a Cu plated layer 34 is formed on the electroless plated layer 33 by electrolytic plating. Specifically, the Cu plated layer 34 is also formed on the inner side surfaces of the through-holes 7, 8, 9, and 10 and the upper surface of the Cu foil 32. On the upper surface of the Cu foil 32, the Cu foil 32, the electroless plated layer 33, and the Cu plated layer 34 are stacked and short-circuited. It should be noted that in descriptions of FIG. 5 and subsequent drawings, the Cu foil 32, the electroless plated layer 33, and the Cu plated layer 34 are considered to be a single component and shown as the Cu plated layer 34.

As shown in FIG. 5, using a publicly known photolithographic technique, a photoresist (not shown) is formed as an etching mask on the upper surface of the Cu plated layer 34 which is to be used as a wiring layer 5. Then, the Cu plated layer 34 is selectively etched by, for example, wet etching using an etchant, e.g., ferric chloride or copper chloride to form the wiring layer 5.

Next, the protective film for covering the upper surface of the Cu foil 31 is removed, and then the Cu foil 31 attached to the front surface side of the insulating base material 4 is stripped. In this stripping step, chemical etching using ferric chloride or copper chloride may be used. The Cu foil on the insulating base material 4 is entirely removed. Accordingly, the wiring layer 5 is exposed to the front surface side of the insulating base material 4 having the through-holes 7, 8, 9, and 10 formed therein.

As shown in FIG. 6, the insulating base material 4 is etched from the front surface side thereof to cause a portion of the wiring layer 5 to protrude from the front surface of the insulating base material 4. As a method of etching the insulating base material 4, dry etching or wet etching may be used. In the case of dry etching, the insulating base material 4 is etched in, for example, a mixed atmosphere of oxygen and nitrogen under the following conditions: plasma output is 50 to 150 W, and treatment time is 3 to 30 min. On the other hand, in the case of wet etching, the insulating base material 4 is etched using, for example, an aqueous solution consisting primarily of sodium permanganate and sodium hydroxide as an etchant under the following conditions: treatment temperature is 70 to 85° C., and treatment time is 5 to 30 min. By such an etching step, protruding portions 11, 12, 13, and 14 having heights of, for example, approximately 10 to 30 μm are formed on the front surface side of the insulating base material 4.

As described previously using FIG. 1B, the protruding portions 11, 12, 13, and 14 are used as bump electrodes. Accordingly, any design change can be made to the protruding heights of the protruding portions 11, 12, 13, and 14 in accordance with use by changing treatment time. In other words, in this embodiment, since the protruding heights of the protruding portions 11, 12, 13, and 14 can be easily changed by changing etching time without changing fabrication equipment (including molds and the like), the simplification of a fabrication method and a reduction of fabrication cost can be realized.

As shown in FIG. 7, a semiconductor element 2 is mounted on the protruding portions 11, 12, 13, and 14 to be used as bump electrodes. For example, conductive materials 25, 26, 27, and 28 such as solder cream are applied on the protruding portions 11, 12, 13, and 14 by screen printing. Then, the semiconductor element 2 is mounted so that the bump electrodes 21, 22, 23, and 24 of the semiconductor element 2 may be located on the protruding portions 11, 12, 13, and 14, by, for example, a flip-chip bonding technique, and reflow is performed to mount the semiconductor element 2 on the insulating base material 4.

Next, an underfill 29 is injected into the gap between the semiconductor element 2 and the insulating base material 4. For example, using epoxy resin as the underfill 29, the underfill 29 in the form of a liquid is injected from one side or two sides of the semiconductor element 2 by, for example, a capillary method and then heated to be cured. It should be noted that the viscosity of the underfill 29 can be adjusted by changing the content of filler mixed in the underfill 29.

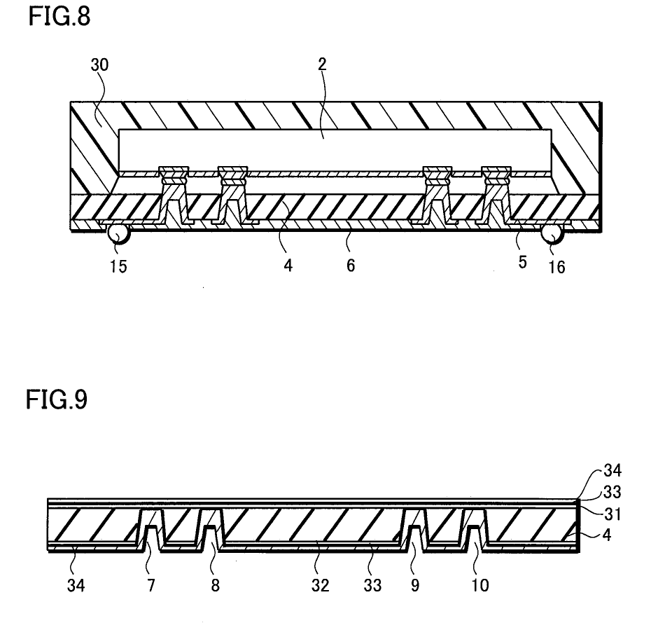

As shown in FIG. 8, sealing resin 30 is formed to cover upper surfaces of the semiconductor element 2 and the insulating base material 4. In the case where the sealing resin 30 is formed by transfer molding, thermosetting resin is used. In the case where the sealing resin 30 is formed by injection molding, thermoplastic resin is used.

Next, a covering layer 6 is formed to cover the wiring layer 5 disposed in a pattern on the back surface side of the insulating base material 4. As the covering layer 6, thermosetting resin such as epoxy resin, or thermoplastic resin such as polyethylene, is used. Then, opening portions are formed in the covering layer 6 on portions of the wiring layer 5 in which external electrodes 15 and 16 are to be formed. Using the opening portions, the external electrodes 15 and 16 made of, for example, solder balls are formed.

The above-described fabrication method can be changed as follows. Specifically, though in the description made with reference to FIG. 4, electroless plating and electrolytic plating are performed with the upper surface of the Cu foil 31 covered with a protective film, both plating processes can be performed without using this protective film. FIG. 9 shows a result of performing both plating processes without using a protective film. Referring to this drawing, the upper surface of the Cu foil 31 is covered with the electroless plated layer 33 and the Cu plated layer 34. The wiring layer 5 is formed in this state as shown in FIG. 5, and the Cu foil 31, the electroless plated layer 33, and the Cu plated layer 34 which cover the upper surface of the insulating base material 4 are removed. Here, the removal of the Cu foil 31, the electroless plated layer 33, and the Cu plated layer 34 and the formation of the wiring layer 45 may be performed at the same time, or one of the removal and the formation may be performed before the other.

### Second Embodiment

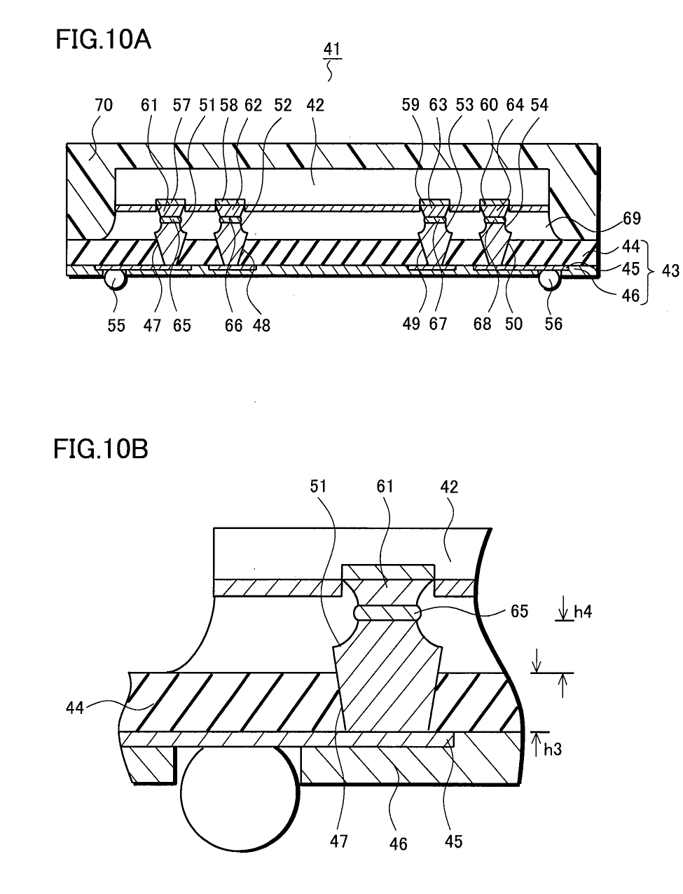

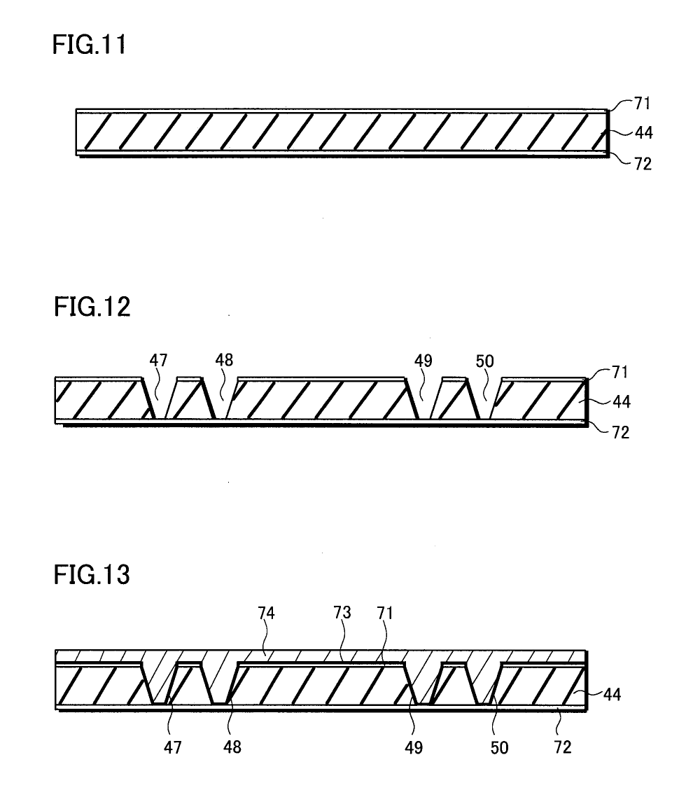

Hereinafter, a description will be made of a circuit device using an element mounting substrate of this embodiment and a method of fabricating the circuit device using the element mounting substrate with reference to FIGS. 10A to 17. The second embodiment is characterized by differing from the above-described first embodiment in protruding structures of bump electrodes 51, 52, 53, and 54 and in a method of forming the bump electrodes 51, 52, 53, and 54. FIG. 10A is a cross-sectional view for explaining the circuit device using the element mounting substrate of this embodiment. FIG. 10B is a cross-sectional view for explaining a bump electrode of this embodiment. FIGS. 11 to 17 are cross-sectional views for explaining the method of fabricating the circuit device using the element mounting substrate of this embodiment. It should be noted that in an explanation of the circuit device and the method of fabricating the same in FIGS. 10A to 17, the element mounting substrate and a method of fabricating the same will be described together.

First, the circuit device using the element mounting substrate will be described with reference to FIGS. 10A and 10B.

As shown in FIGS. 10A and 10B, a circuit device 41 is a resin-sealed CSP having slightly larger outside dimensions than that of a semiconductor element 42 embedded therein. The appearance of the circuit device 41 is in the shape of a rectangular parallelepiped or a cube. It should be noted that though in this embodiment a description will be made of the case of a CSP-type circuit device, the present application is not limited to this. For example, in the case of a WLP in which outside dimensions of a circuit device have substantially the same dimensions as those of a semiconductor element mounted thereon, similar effects can also be obtained.

An element mounting substrate 43 principally includes an insulating base material 44, a wiring layer 45 formed on the insulating base material 44, and a covering layer 46 for covering a back surface side of the insulating base material 44. It should be noted that the covering layer 46 may or may not be disposed on the back surface side of the insulating base material 44.

The insulating base material 44 is glass epoxy or the like obtained by impregnating fiberglass with epoxy resin, and is an interposer based on a resin material. The film thickness of the insulating base material 44 is, for example, 30 to 80 μm.

The insulating base material 44 has the semiconductor element 42 mounted on the front surface side thereof, and has the wiring layer 45 formed on the back surface side thereof. The insulating base material 44 also has the function of mechanically supporting the semiconductor element 42 in a fabrication process. The insulating base material 44 may be made of a material other than a resin-based material, and, for example, may be a substrate made of ceramic or an inorganic material such as Si, or a substrate in which a substrate such as a metal substrate made of metal such as copper or aluminum is covered and insulated by an insulating layer made of resin or the like.

The wiring layer 45 is formed by selectively etching a Cu plated layer formed by, for example, electrolytic plating or the like. The film thickness of the wiring layer 45 is, for example, approximately 20 to 50 μm. The wiring layer 45 is disposed in a pattern on the back surface side of the insulating base material 44. The wiring layer 45 protrudes from the front surface of the insulating base material 44 through through-holes 47, 48, 49, and 50 formed in the insulating base material 44. Protruding portions 51, 52, 53, and 54 of the wiring layer 45 protrude above the through-holes 47, 48, 49, and 50 to be used as bump electrodes. It should be noted that though the protruding portions 51, 52, 53, and 54 protrude approximately 10 to 30 μm from a front surface of the insulating base material 44, any design change can be made to the protruding heights thereof in accordance with use. On the front surface side of the insulating base material 44, the wiring layer 45 is not disposed in a pattern, but only the protruding portions 51, 52, 53, and 54 are formed.

The covering layer 46 covers the back surface side of the insulating base material 44. In the covering layer 46, opening portions are formed in areas where external electrodes 55 and 56 are formed. The covering layer 46 is made of thermosetting resin such as epoxy resin or thermoplastic resin such as polyethylene. The thicknesses of portions of the covering layer 46 which cover the upper surface of the wiring layer 45 are, for example, approximately 20 to 100 μm. It should be noted that the covering layer 46 may also be a solder resist (PSR).

The external electrodes 55 and 56 are made of a conductive material such as solder and provided in the form of a grid on the back surface side of the insulating base material 44 to constitute a BGA. The external electrodes 55 and 56 are electrically connected to the semiconductor element 42 embedded in the circuit device 41 through the wiring layer 45. It should be noted that since an SIP or the like may also be employed as a circuit device, the external electrodes 55 and 56 may be disposed in the form of a ring in the periphery of the insulating base material 44 or may be randomly disposed.

The semiconductor element 42 (circuit element) is connected to the top of the insulating base material 44 through the protruding portions 51, 52, 53, and 54. Specifically, on pad electrodes 57, 58, 59, and 60 of the semiconductor element 42, bump electrodes 61, 62, 63, and 64 made of, for example, Au are formed. The bump electrodes 61, 62, 63, and 64 of the semiconductor element 42 are respectively mounted on the protruding portions 51, 52, 53, and 54 with conductive materials 65, 66, 67, and 68 interposed therebetween by, for example, a flip-chip bonding technique. The conductive materials 65, 66, 67, and 68 are made of solder cream, brazing material, conductive paste, or the like.

It should be noted that though in this embodiment a description has been made of the case where the bump electrodes 61, 62, 63, and 64 are formed on the semiconductor element 42 side, the present invention is not limited to this case. For example, the present invention may be applied to the case where the pad electrodes 57, 58, 59, and 60 are electrically connected directly to the protruding portions 51, 52, 53, and 54 through the conductive materials 65, 66, 67, and 68, respectively. Further, the present invention may be applied to the case of resin bonding in which liquid resin or a resin sheet is disposed on the insulating base material 44 having the protruding portions 51, 52, 53, and 54 disposed therein and in which the semiconductor element 42 and the insulating base material 44 are connected to each other by applying pressure when mounting the semiconductor element 42 thereon and by curing the resin.

The semiconductor element 42 is employed here as a circuit element embedded in the circuit device 41. However, other circuit element may be employed. Specifically, an active element such as an IC, an LSI, a discrete transistor, or a discrete diode may be employed as a circuit element. Further, a passive element such as a chip resistor, a chip capacitor, or a sensor may be employed as a circuit element. Moreover, a system configured by internally connecting multiple passive and active elements in combination may be built in the circuit device 41. In this case, protruding portions of the wiring layer 45 are further disposed on the front surface side of the insulating base material 44, and passive elements such as a chip resistor are disposed adjacent to the semiconductor element 42 shown in FIG. 10A.

It should be noted that this element mounting substrate 43 can be applied to a module having only a circuit element mounted thereon, and a circuit device having a totally sealed substrate. Further, possible circuit elements to be mounted on such a substrate or such a circuit device are a semiconductor chip and a passive element. Also, these circuit elements are provided three-dimensionally in such a manner that multiple semiconductor chips are stacked, or provided two-dimensionally. In this way, multiple circuit elements are provided to constitute a system.

An underfill 69 is disposed to fill the gap between the semiconductor element 42 and the insulating base material 44 and made of, for example, epoxy resin. The underfill 69 is also used as a reinforcing material for bump connecting portions against thermal stress caused by the difference in thermal expansion coefficients between the semiconductor element 42 and the insulating base material 44. It should be noted that the thermal expansion coefficient and viscosity of the underfill 69 are adjusted by changing the content of filler mixed in the epoxy resin.

Sealing resin 70 is formed to cover the upper surfaces of the semiconductor element 42 and the insulating base material 44, and is made of thermosetting resin formed by transfer molding or thermoplastic resin formed by injection molding.

As shown in FIG. 10B, the insulating base material 44 has the through-hole 47 formed therein which penetrates from the back surface side thereof to the front surface side thereof. The wiring layer 45 is disposed in a pattern on the back surface side of the insulating base material 44, and fills the through-hole 47 to protrude from the front surface of the insulating base material 44. Although details will be described later when a circuit device fabrication method is described, the protruding portion 51 is formed by etching the insulating base material 44 from the front surface side of the insulating base material 44. Since the wiring layer 45 has a structure in which the wiring layer 45 is buried in the insulating base material 44, the thickness of the element mounting substrate 43 can be reduced by a thickness h3 of each portion of the wiring layer 45 which is used as a bump electrode. Further, the thickness of the circuit device 41 can be reduced.

On the other hand, a protruding height h4 by which the wiring layer 45 protrudes from the front surface side of the insulating base material 44 is arbitrarily set in accordance with use when the wiring layer 45 is used as bump electrodes, by adjusting the amount of etching of the insulating base material 44. The distance between the insulating base material 44 and the semiconductor element 42 can be increased by increasing the protruding height h4. Thus, it is possible to reduce damage to the conductive material 65 due to thermal stress caused by the difference in thermal expansion coefficients between the insulating base material 44 and the semiconductor element 42, and to improve connection reliability. Further, by increasing the protruding height h4, the bump electrode 61 on the semiconductor element 42 side can be omitted, or the height of the bump electrode 61 can be reduced.

Next, a method of fabricating the circuit device using the element mounting substrate shown in FIG. 10A will be described with reference to FIGS. 11 to 17. It should be noted that the same components as those of the circuit device using the element mounting substrate shown in FIG. 10A are denoted by the same reference numerals.

As shown in FIG. 11, an insulating base material 44 is prepared, and Cu foil 71 and 72 as conductive members is attached to the entire front and back surfaces of the insulating base material 44 by, for example, plating, vapor deposition, sputtering, or rolling. The conductive members may be Al, Fe, or Fe—Ni foil other than Cu. As described previously, the insulating base material 44 is made of a resin material, an inorganic material, or a metal material (including a metal material having an insulated surface). The insulating base material 44 also has the function of mechanically supporting the semiconductor element 42 (see FIG. 10A) in a fabrication process.

As shown in FIG. 12, through-holes 47, 48, 49, and 50 are formed from the front surface side of the insulating base material 44. Using a publicly known photolithographic technique, opening portions are formed in the Cu foil 71 on areas where the through-holes 47, 48, 49, and 50 are to be formed, by wet etching using an etchant, e.g., ferric chloride or copper chloride. Then, using the Cu foil 71 as a mask, the insulating base material 44 is removed with a carbon dioxide laser until the Cu foil 72 is exposed. Thus, the through-holes 47, 48, 49, and 50 are formed. It should be noted that after the insulating base material 44 is evaporated with the carbon dioxide laser, if residues exist in bottom portions of the through-holes 47, 48, 49, and 50, the residues are removed by wet etching using an etchant such as sodium permanganate or ammonium persulfate.

As shown in FIG. 13, an electroless plated layer 73 having a thickness of, for example, approximately 1 μm is deposited by electroless plating on the insulating base material 44 at inner side surfaces of the through-holes 47, 48, 49, and 50, on the Cu foil 72 at bottom portions of the through-holes 47, 48, 49, and 50, and on the Cu foil 71 on the front surface side of the insulating base material 44. At this time, the electroless plated layer 73 is also attached to the front surface side of the Cu foil 71 and the upper surface of the insulating base material 44. The electroless plated layer 73 may be made of the same material as the Cu foil 71 and 72 (e.g., Cu) or other metal material. It should be noted that in this step, since the lower surface of the Cu foil 72 is covered by a protective film (not shown), a plated metal film is not attached to the Cu foil 72.

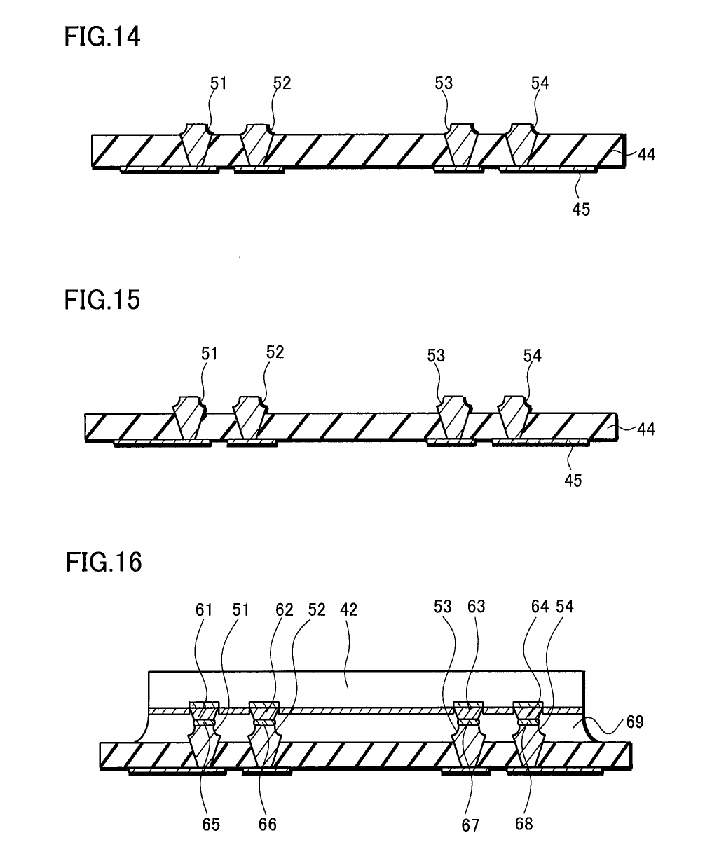

Next, using the electroless plated layer 73 like a plated wire for power supply, a Cu plated layer 74 is formed on the electroless plated layer 73 by filling electrolytic plating. Specifically, the Cu plated layer 74 fills the inner side surfaces of the through-holes 47, 48, 49, and 50, and is also formed on the upper surface of the Cu foil 71. On the upper surfaces of the Cu foil 71 and 72, the Cu foil 71 and 72, the electroless plated layer 73, and the Cu plated layer 74 are stacked and short-circuited. It should be noted that in descriptions of FIG. 14 and subsequent drawings, the Cu foil 71 and 72, the electroless plated layer 73, and the Cu plated layer 74 are considered to be a single component and shown as the Cu plated layer 74.

As shown in FIG. 14, on the front surface side of the insulating base material 44, the Cu plated layer 74 (see FIG. 13) is etched to form protruding portions 51, 52, 53, and 54. On the other hand, on the back surface side of the insulating base material 44, the Cu foil 72 (see FIG. 13) is etched to form a wiring layer 45. Using a publicly known photolithographic technique, a photoresist (not shown) is formed as an etching mask on the upper surfaces of areas where the protruding portions 51, 52, 53, and 54 are to be formed and areas where the wiring layer 45 is to be formed. Then, the Cu plated layer 74 and the Cu foil 72 are selectively etched by, for example, wet etching using an etchant, e.g., ferric chloride or copper chloride to form the protruding portions 51, 52, 53, and 54 and the wiring layer 45.

As shown in FIG. 15, the insulating base material 44 is etched from the front surface side thereof so that the protruding portions 51, 52, 53, and 54 may have a desired protruding height. As a method of etching the insulating base material 44, dry etching or wet etching may be used. In the case of dry etching, the insulating base material 44 is etched in, for example, a mixed atmosphere of oxygen and nitrogen under the following conditions: plasma output is 50 to 150 W, and treatment time is 3 to 30 min. On the other hand, in the case of wet etching, the insulating base material 44 is etched using, for example, an aqueous solution consisting primarily of sodium permanganate and sodium hydroxide as an etchant under the following conditions: treatment temperature is 70 to 85° C., and treatment time is 5 to 30 min. By such an etching step, protruding portions 51, 52, 53, and 54 having heights of, for example, approximately 10 to 30 μm are formed on the front surface side of the insulating base material 44.

In this embodiment, as described previously using FIG. 10B, the protruding portions 51, 52, 53, and 54 are used as bump electrodes. Accordingly, any design change can be made to the protruding heights of the protruding portions 51, 52, 53, and 54 in accordance with use by changing treatment time. In other words, since the protruding heights of the protruding portions 51, 52, 53, and 54 can be easily changed by changing etching time without changing fabrication equipment (including fabrication tools and the like), the simplification of a fabrication method and a reduction of fabrication cost can be realized.

As shown in FIG. 16, a semiconductor element 42 is mounted on the protruding portions 51, 52, 53, and 54 to be used as bump electrodes. For example, conductive materials 65, 66, 67, and 68 such as solder cream are applied on the protruding portions 51, 52, 53, and 54 by screen printing. Then, the semiconductor element 42 is mounted so that the bump electrodes 61, 62, 63, and 64 of the semiconductor element 42 may be located on the protruding portions 51, 52, 53, and 54, by, for example, a flip-chip bonding technique, and reflow is performed to mount the semiconductor element 42 on the insulating base material 44.

Next, an underfill 69 is injected into the gap between the semiconductor element 42 and the insulating base material 44. For example, using epoxy resin as the underfill 69, the underfill 69 in the form of a liquid is injected from one side or two sides of the semiconductor element 42 by, for example, a capillary method and then heated to be cured. It should be noted that the viscosity of the underfill 69 can be adjusted by changing the content of filler mixed in the underfill 69.

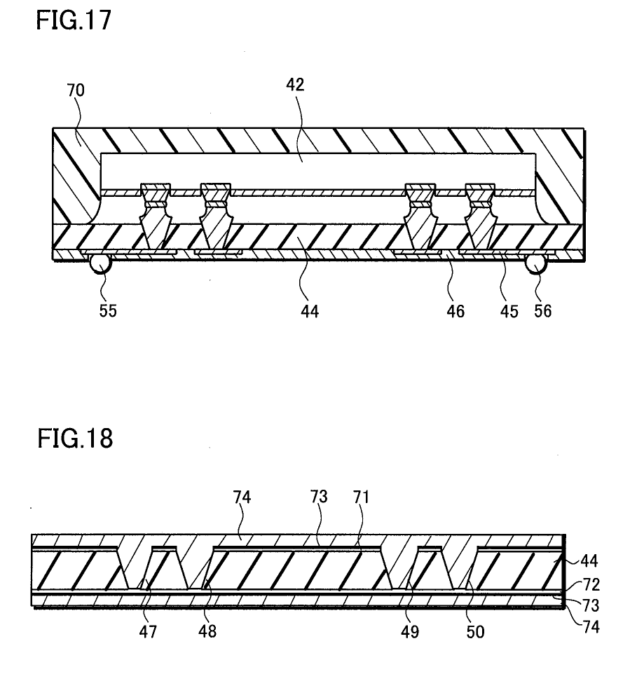

As shown in FIG. 17, sealing resin 70 is formed to cover upper surfaces of the semiconductor element 42 and the insulating base material 44. In the case where the sealing resin 70 is formed by transfer molding, thermosetting resin is used. In the case where the sealing resin 70 is formed by injection molding, thermoplastic resin is used.

Next, a covering layer 46 is formed to cover the wiring layer 45 disposed in a pattern on the back surface side of the insulating base material 44. As the covering layer 46, thermosetting resin such as epoxy resin, or thermoplastic resin such as polyethylene, is used. Then, opening portions are formed in the covering layer 46 on portions of the wiring layer 45 in which external electrodes 55 and 56 are to be formed. Using the opening portions, the external electrodes 55 and 56 made of, for example, solder balls are formed.

The above-described fabrication method can be changed as follows. Specifically, though in the description made with reference to FIG. 13, plating is performed in a state in which the Cu foil 72 provided on the lower surface of the insulating base material 44 is covered by a protective film, plating may be performed without using this protective film. Referring to FIG. 18, in this case, the electroless plated layer 73 and the Cu plated layer 74 are stacked on the lower surface of the Cu foil 72. This increases the thickness of the metal film covering the lower surface of the insulating base material 44. As a result, referring to FIG. 14, the wiring layer 45, which is formed by selectively etching this metal film, is also formed to have an increased thickness.

### Third Embodiment

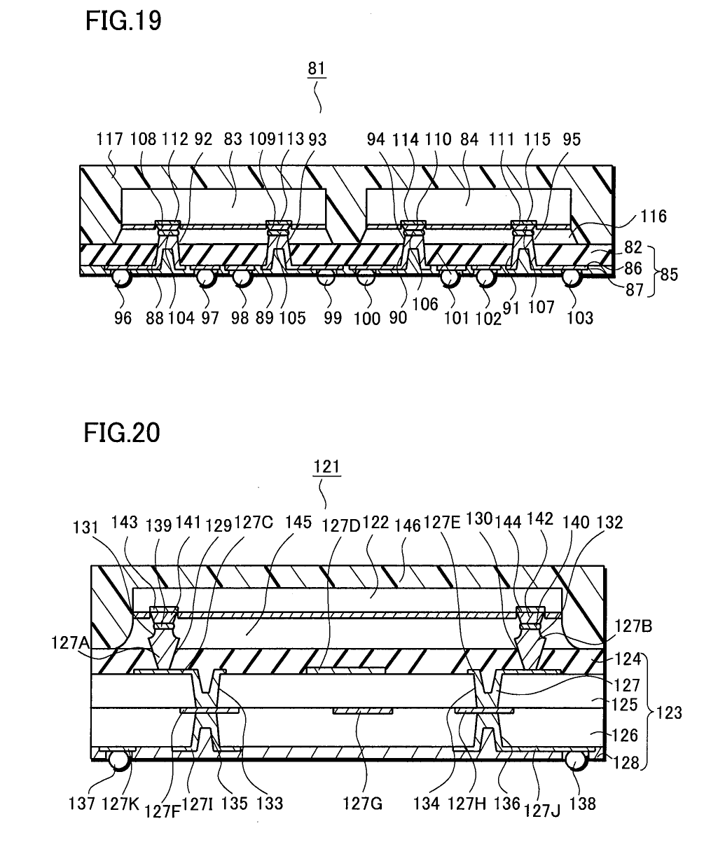

Hereinafter, a description will be made of a circuit device using an element mounting substrate of this embodiment, specifically, a multichip module, with reference to FIG. 19. FIG. 19 is a cross-sectional view for explaining the circuit device using the element mounting substrate of this embodiment. It should be noted that in this embodiment, since the structures of protruding portions to be used as bump electrodes of the element mounting substrate are similar to those of the bump electrodes of the aforementioned first embodiment, the description of the first embodiment is appropriately referenced.

As shown in the drawing, a circuit device 81 is configured as a multichip module in which semiconductor elements 83 and 84 are mounted on an insulating base material 82. The semiconductor elements 83 and 84 are mounted in the form of a bare chip on the insulating base material 82. Thus, high-density packaging is realized, and the miniaturization of the circuit device 81 is realized. It should be noted that though only the semiconductor elements 83 and 84 are shown in FIG. 19, the present invention may be applied to the case where multiple semiconductor elements (circuit elements) are mounted.

An element mounting substrate 85 principally includes the insulating base material 82, a wiring layer 86 formed on the insulating base material 82, and a covering layer 87 for covering a back surface side of the insulating base material 82. It should be noted that the covering layer 87 may or may not be disposed on the back surface side of the insulating base material 82.

The insulating base material 82 is made of a resin material, an inorganic material, or a metal material (including a metal material having an insulated surface). The insulating base material 82 also has the function of mechanically supporting the semiconductor elements 83 and 84 in a fabrication process.

The wiring layer 86 is formed by selectively etching a Cu plated layer formed by, for example, electrolytic plating or the like. The wiring layer 86 is disposed in a pattern on the back surface side of the insulating base material 82. The wiring layer 86 protrudes from a front surface of the insulating base material 82 through through-holes 88, 89, 90, and 91 formed in the insulating base material 82. Protruding portions 92, 93, 94, and 95 of the wiring layer 86 protrude above the through-holes 88, 89, 90, and 91 to be used as bump electrodes. It should be noted that though the protruding portions 92, 93, 94, and 95 protrude approximately 10 to 30 μm from a front surface of the insulating base material 82, any design change can be made to the protruding heights thereof in accordance with use.

The covering layer 87 covers the back surface side of the insulating base material 82. In the covering layer 87, opening portions are formed in areas where external electrodes 96, 97, 98, 99, 100, 101, 102, and 103 are formed. The covering layer 87 is made of thermosetting resin such as epoxy resin, or thermoplastic resin such as polyethylene.

The external electrodes 96, 97, 98, 99, 100, 101, 102, and 103 are formed on the back surface side of the insulating base material 82 and provided in the form of a grid to constitute a BGA.

The semiconductor elements 83 and 84 (circuit elements) are mounted on the protruding portions 92, 93, 94, and 95 with conductive materials 104, 105, 106, and 107 interposed therebetween, respectively.

It should be noted that though a description has been made in this embodiment of the case where the bump electrodes 108, 109, 110, and 111 are formed on the side of the semiconductor elements 83 and 84, the present invention is not limited to this case. For example, the present invention may be applied to the case where pad electrodes 112, 113, 114, and 115 of the semiconductor elements 83 and 84 are electrically connected directly to the protruding portions 92, 93, 94, and 95 of the wiring layer 86 through the conductive materials 104, 105, 106, and 107, respectively. Further, the present invention may be applied to the case of resin bonding using liquid resin or a resin sheet.

In the shown structure, the semiconductor elements 83 and 84 are embedded in the circuit device 81. However, an active element such as an IC, an LSI, a discrete transistor, or a discrete diode may be embedded therein as other circuit element. Moreover, a passive element such as a chip resistor, a chip capacitor, or a sensor may also be embedded in the circuit device 81, and a system may be built in which multiple passive and active elements are internally connected in combination.

An underfill 116 is disposed to fill the gap between each of the semiconductor elements 83 and 84 and the insulating base material 82. The underfill 116 is made of, for example, epoxy resin.

Sealing resin 117 is made of thermosetting resin formed by transfer molding or thermoplastic resin formed by injection molding.

In the multichip module of this embodiment, portions of the wiring layer 86 which are used as bump electrodes also penetrate the insulating base material 82. Accordingly, the thickness of the element mounting substrate 85 can be reduced. Further, the thickness of the circuit device 81 can be reduced. Moreover, the protruding heights of the protruding portions 92, 93, 94, and 95 to be used as bump electrodes are arbitrarily adjusted in accordance with the amount of etching of the insulating base material 82.

It should be noted that though a description has been made in this embodiment of the case where the protruding portions to be used as bump electrodes have the same structures as those described in the first embodiment, the present invention is not limited to this case. For example, similar effects can also be obtained in the case where the protruding portions to be used as bump electrodes have the same structures as those described in the second embodiment.

### Fourth Embodiment

Hereinafter, a description will be made of a circuit device using an element mounting substrate of this embodiment, specifically, a circuit device having a multilayer wiring structure, with reference to FIG. 20. FIG. 20 is a cross-sectional view for explaining the circuit device using the element mounting substrate of this embodiment. It should be noted that in this embodiment, since the structures of protruding portions to be used as bump electrodes of the element mounting substrate are similar to those of the bump electrodes of the aforementioned second embodiment, the description of the second embodiment is appropriately referenced.

As shown in the drawing, a circuit device 121 is a resin-sealed CSP having slightly larger outside dimensions than that of a semiconductor element 122 embedded therein. The appearance of the circuit device 121 is in the shape of a rectangular parallelepiped or a cube. It should be noted that though in this embodiment a description will be made of the case of a CSP-type circuit device, the present application is not limited to this. For example, in the case of a WLP in which outside dimensions of a circuit device have substantially the same dimensions as those of a semiconductor element mounted thereon, similar effects can also be obtained.

An element mounting substrate 123 principally includes a first insulating base material 124, a second insulating base material 125, a third insulating base material 126, a three-layered multilayer wiring layer 127 formed on the first to third insulating base materials 124, 125, and 126, and a covering layer 128 for covering the back surface side of the third insulating base material 126. It should be noted that the covering layer 128 may or may not be disposed on the back surface side of the third insulating base material 126.

The first to third insulating base materials 124, 125, and 126 are made of a resin material, an inorganic material, or a metal material (including a metal material having an insulated surface) and stacked on top of each other. The first to third insulating base materials 124, 125, and 126 also have the function of mechanically supporting the semiconductor element 122 in a fabrication process.

The first insulating base material 124 has through-holes 129 and 130 formed therein. The insides of the through-holes 129 and 130 are filled with wiring layers 127A and 127B. The wiring layers 127A and 127B are Cu plated layers formed by, for example, filling electrolytic plating. The wiring layers 127A and 127B protrude from a front surface of the first insulating base material 124. Protruding portions 131 and 132 of the wiring layers 127A and 127B are used as bump electrodes. It should be noted that though the protruding portions 131 and 132 of the wiring layers 127A and 127B protrude approximately 10 to 30 μm from a front surface of the first insulating base material 124, any design change can be made to the protruding heights thereof in accordance with use.

The second insulating base material 125 has wiring layers 127C, 127D, and 127E formed on a front surface side thereof, and has wiring layers 127F, 127G, and 127H formed on the back surface side thereof. The wiring layer 127C is connected to the wiring layer 127A, and is wired to a back surface side of the second insulating base material 125 through a through-hole 133 to be connected to the wiring layer 127F. Similarly, the wiring layer 127E is connected to the wiring layer 127B, and is wired to the back surface side of the second insulating base material 125 through a through-hole 134 to be connected to the wiring layer 127H. The wiring layers 127C, 127D, and 127E are formed by selectively etching a Cu plated layer formed by, for example, electrolytic plating or the like. The wiring layers 127F, 127G, and 127H are formed by, for example, etching Cu foil attached to the second insulating base material 125.

The third insulating base material 126 has wiring layers 127I, 127J, and 127K formed thereon. The wiring layer 127I is connected to the wiring layer 127F, and is wired to the back surface side of the third insulating base material 126 through a through-hole 135. Similarly, the wiring layer 127J is connected to the wiring layer 127H, and is wired to the back surface side of the third insulating base material 126 through a through-hole 136. The wiring layers 127I, 127J, and 127K are formed by selectively etching a Cu plated layer formed by, for example, electrolytic plating or the like. The wiring layers 127I, 127J, and 127K are disposed in a pattern on the back surface side of the third insulating base material 126.

The covering layer 128 covers the back surface side of the third insulating base material 126. In the covering layer 128, opening portions are formed in areas where external electrodes 137 and 138 are formed. The covering layer 128 is made of thermosetting resin such as epoxy resin, or thermoplastic resin such as polyethylene.

The external electrodes 137 and 138 are formed on the back surface side of the third insulating base material 126 and provided in the form of a grid to constitute a BGA.

The semiconductor element 122 (circuit element) is mounted on the protruding portions 131 and 132 with conductive materials 139 and 140 interposed therebetween, respectively.

It should be noted that though a description has been made in this embodiment of the case where bump electrodes 141 and 142 are formed on the semiconductor element 122 side, the present invention is not limited to this case. For example, the present invention may be applied to the case where pad electrodes 143 and 144 of the semiconductor element 122 are electrically connected directly to the protruding portions 131 and 132 of the wiring layers 127A and 127B through the conductive materials 139 and 140, respectively. Further, the present invention may be applied to the case of resin bonding using liquid resin or a resin sheet.

In the shown structure, the semiconductor element 122 is embedded in the circuit device 121. However, an active element such as an IC, an LSI, a discrete transistor, or a discrete diode may be embedded therein as other circuit element. Moreover, a passive element such as a chip resistor, a chip capacitor, or a sensor may also be embedded in the circuit device 121, and a system may be built in which multiple passive and active elements are internally connected in combination.

An underfill 145 is disposed to fill the gap between the semiconductor element 122 and the first insulating base material 124. The underfill 145 is made of, for example, epoxy resin.

Sealing resin 146 is made of thermosetting resin formed by transfer molding or thermoplastic resin formed by injection molding.

In the multichip module of this embodiment, portions of the wiring layers 127A and 127B which are used as bump electrodes also penetrate the first insulating base material 124. Accordingly, the thickness of the element mounting substrate 123 can be reduced. Further, the thickness of the circuit device 121 can be reduced. Moreover, the protruding heights of the protruding portions 131 and 132 to be used as bump electrodes are arbitrarily adjusted in accordance with the amount of etching of the first insulating base material 124.

It should be noted that though a description has been made in this embodiment of the case where the protruding portions to be used as bump electrodes have the same structures as those described in the second embodiment, the present invention is not limited to this case. For example, similar effects can also be obtained in the case where the protruding portions to be used as bump electrodes have the same structures as those described in the first embodiment.

### Fifth Embodiment

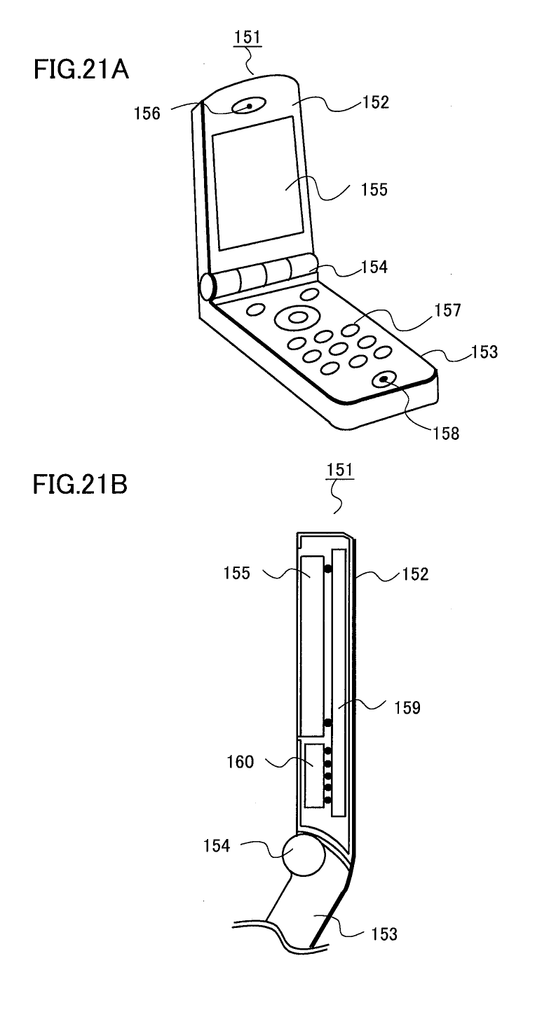

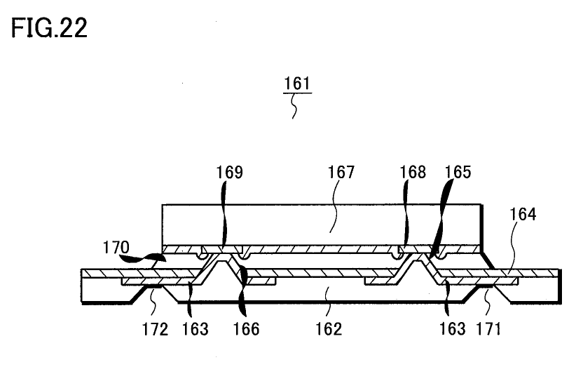

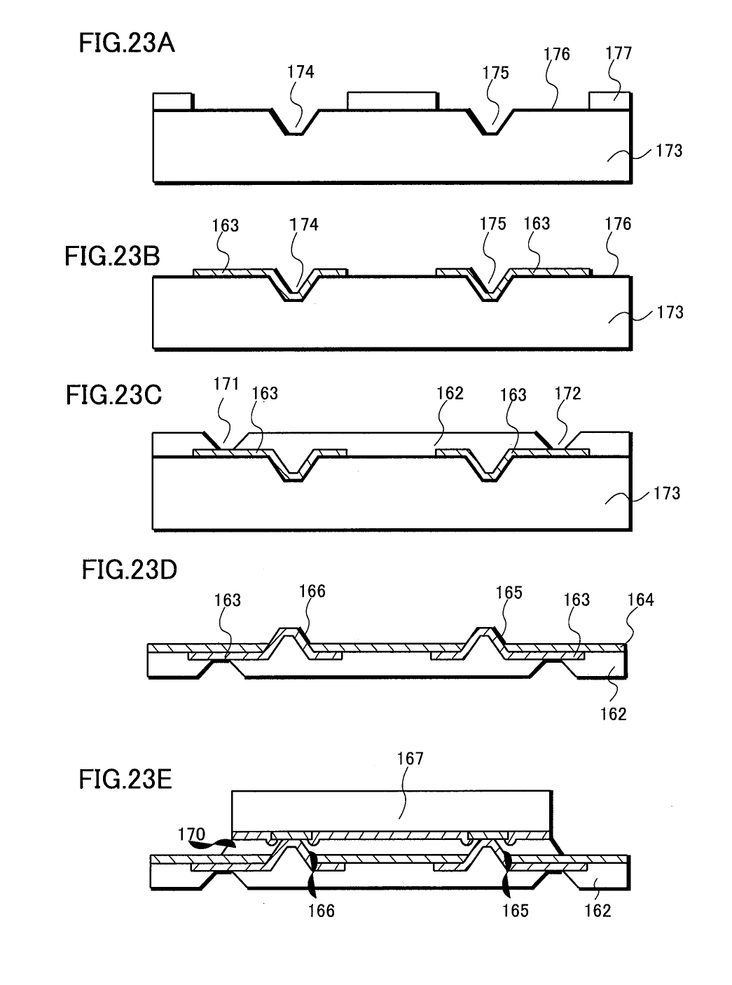

Hereinafter, a description will be made of a mobile appliance equipped with a circuit device using an element mounting substrate of this embodiment, specifically, a mobile phone, with reference to FIGS. 21A and 21B. FIG. 21A is a perspective view for explaining the mobile phone equipped with the circuit device using the element mounting substrate of this embodiment. FIG. 21B is a cross-sectional view for explaining the internal structure of the mobile phone of this embodiment. It should be noted that the circuit device mounted on the mobile phone of this embodiment is any one of the circuit devices described in the above-described first to fourth embodiments, and the description of the first to fourth embodiments is appropriately referenced.

As shown in FIG. 21A, a mobile phone 151 includes an appliance body including a first casing 152 and a second casing 153. The first casing 152 and the second casing 153 are connected to each other with a movable portion 154. The first casing 152 and the second casing 153 can turn about the movable portion 154.

A display portion 155 is provided in the first casing 152. The display portion 155 is made of, for example, a liquid crystal display (LCD). On the display portion 155, information such as characters and images is displayed.

A speaker portion 156 is provided above the display portion 155 in the first casing 152.

An operating portion 157 is provided in the second casing 153. The operating portion 157 includes a power key for turning on power, a mail key for starting a mail mode, a cross key, number/letter keys, and the like.

A microphone portion 158 is provided below the operating portion 157 in the second casing 153.

As shown in FIG. 21B, inside the first casing 152, a printed board 159 is disposed on a rear side thereof. The display portion 155, a circuit device 160, and the like are mounted on the printed board 159. The circuit device 160, the display portion 155, and the like are electrically connected to each other through a wiring layer or layers on the printed board 159. The circuit device 160 of this embodiment is used as a power supply circuit for driving each circuit, an RF generation circuit for generating RF (Radio Frequency) signals, a DAC (Digital Analog Converter) circuit, an encoder circuit, a driver circuit for a backlight as a light source of a liquid crystal panel, and the like.

As described previously, in the circuit device 160, by reducing the thickness of the element mounting substrate on which circuit elements are mounted, a reduction in the thickness and size of the circuit device 160 is realized. As a result, the proportion of the circuit device 160 to the mobile phone 151 in the thickness direction is reduced, and a reduction in the thickness of the mobile phone 151 is realized.

It should be noted that though in this embodiment a description has been made using a mobile phone as a mobile appliance, the present invention is not limited to this case. For example, the mobile appliance may be electronic appliances such as a personal mobile terminal (PDA), a digital video camera (DVC), a music player, or a digital still camera (DSC).
1 CIRCUIT DEVICE
2 SEMICONDUCTOR ELEMENT
3 ELEMENT MOUNTING SUBSTRATE
4 INSULATING BASE MATERIAL
5 WIRING LAYER
6 COVERING LAYER
7 THROUGH-HOLE
11 PROTRUDING PORTION
17 PAD ELECTRODE
21 BUMP ELECTRODE
25 CONDUCTIVE MATERIAL
29 UNDERFILL
30 SEALING RESIN
31 Cu FOIL
33 ELECTROLESS PLATED LAYER
41 CIRCUIT DEVICE
81 CIRCUIT DEVICE
121 CIRCUIT DEVICE
151 MOBILE PHONE

1. An element mounting substrate comprising:
an insulating base material having first and second main surfaces opposing each other;
a through-hole penetrating the insulating base material from the second main surface to the first main surface;
a wiring layer on the second main surface of the insulating base material;
a protrusion extending from the wiring layer through the through-hole to the first main surface of the insulating base material from which the protrusion protrudes.

2. The element mounting substrate according to claim 1, wherein
a covering layer is formed at a second main surface side of the insulating base material so that a portion of the wiring layer is exposed.

3. The element mounting substrate according to any one of claims 1 and 2, wherein the wiring layer is formed as multilayer wiring on the insulating base material.

4-10. (canceled)

11. A circuit device comprising:
an element mounting substrate; and
a circuit element mounted on the element mounting substrate,
the element mounting substrate including
an insulating base material having first and second main surfaces opposing each other,
a through-hole penetrating the insulating base material,
a wiring layer on the second main surface of the insulating base material, and
a protrusion extending from the wiring layer through the through-hole to the first main surface of the insulating base material from which the protrusion protrudes.

12. The circuit device according to claim 11, wherein a covering layer is formed at a second main surface side of the insulating base material so that a portion of the wiring layer is exposed, and an external electrode is formed on the portion of the wiring layer which is exposed from the covering layer.

13. The circuit device according to claim 11, wherein a plurality of the circuit elements are mounted on the insulating base material.

14. The circuit device according to claim 11, wherein an underfill is disposed between the circuit element and the insulating base material.

15. The circuit device according to claim 11, wherein the wiring layer is formed as multilayer wiring on the insulating base material.

16-26. (canceled)
